(19) United States
(12) Patent Application Publication
(10) Pub. No.: US 2023/0359118 A1
(43) Pub. Date: Nov. 9, 2023

(54) SYSTEMS AND METHODS FOR FORMING STRUCTURES ON A SURFACE

(71) Applicant: ASML HOLDING N.V., 5500 AH Veldhoven, NL (US)

(72) Inventors: Sotrios LYRINTZIS, Danbury, CT (US); Keane Michael LEVY, Wilton, CT (US)

(21) Appl. No.: 17/912,202

(22) PCT Filed: Mar. 16, 2021
(86) PCT No.: PCT/EP2021/056708

§ 371 Date: Sep. 16, 2022

Related U.S. Application Data
(60) Provisional application No. 63/004,694, filed on Apr. 3, 2020.

(51) Int. Cl. G03F 7/00; G03F 7/20

(52) U.S. Cl. CPC G03F 7/0035; G03F 7/2037

(57) ABSTRACT

Systems and methods for forming structures (e.g., a plurality of support peaks) on a surface are described. Forming structures on a surface includes masking one or more portions of the surface; removing material from one or more unmasked portions of the surface; and iteratively repeating the masking and removing to reshape the unmasked portions of the surface until the plurality of structures (e.g., support peaks) are formed such that regions of the surface between individual structures (support peaks) have a target characteristic such as a target topography, roughness, etc.

### CROSS-REFERENCE TO RELATED APPLICATIONS

This application claims priority of U.S. Provisional Patent Application No. 63/004,694, which was filed on Apr. 3, 2020, and which is incorporated herein in its entirety by reference.

### TECHNICAL FIELD

The description herein relates generally to systems and methods for forming structures on a surface.

### BACKGROUND

A lithography (e.g., projection) apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

According to an embodiment, there is provided a method for forming structures such as a plurality of support peaks, on a surface. The method comprises (1) masking one or more portions of the surface; (2) removing material from one or more unmasked portions of the surface; and (3) iteratively repeating (1) and (2) to reshape the unmasked portions of the surface until the plurality of support peaks are formed such that regions of the surface between individual support peaks have a target characteristic.

In an embodiment, the target characteristic is indicative of a desired topography of the surface. In an embodiment, the desired topography comprises one or more of a desired skewness, kurtosis, or p-value of a dimension associated with the plurality of support peaks. In an embodiment, the target characteristic is associated with a quantity and/or dimensional separation of the individual peaks.

In an embodiment, removing material comprises controlling one or more of an angle, a taper, or a shadowing of one or more of the peaks. In an embodiment, one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

In an embodiment, the support peaks are formed to have peak heights within a given dimensional range. In an embodiment, the given dimensional range describes a flatness and/or coplanarity of the peaks.

In an embodiment, the masking is performed by one or more ion beam figuring masks. In an embodiment, removing material is performed by an ion beam.

In an embodiment, the surface is substantially planar and flat before material is removed from the surface. In an embodiment, the surface comprises a top surface of a burl. In an embodiment, the surface forms at least a portion of a wafer table, a wafer clamp gripping surface, a reticle clamp, or reticle handler, in a semiconductor manufacturing apparatus.

In an embodiment, removing material comprises a dry etching process.

In an embodiment, the target characteristic is roughness. In an embodiment, the roughness is about 100 nm or more by RMS, while the support peaks are formed to have peak heights within about 100 nm or less of each other. In an embodiment, the surface comprises a top surface of a burl, and a width of a given dimensional range of peak heights depends on a dimension of the top surface of the burl. In an embodiment, a width of the given dimensional range comprises about 1 um to about 500 um.

According to another embodiment, there is provided a system for forming a plurality of structures such as support peaks on a surface. The system comprises (1) one or more masks configured for masking one or more portions of the surface; and (2) an etcher configured for removing material from one or more unmasked portions of the surface. The one or more masks and the etcher are configured for iteratively repeating the masking and the material removal from the unmasked portions of the surface until the plurality of support peaks are formed such that regions of the surface between individual support peaks have a target characteristic.

In an embodiment, the target characteristic is indicative of a desired topography of the surface. In an embodiment, the desired topography comprises one or more of a desired skewness, kurtosis, or p-value of a dimension associated with the plurality of support peaks. In an embodiment, the target characteristic is associated with a quantity and/or dimensional separation of the individual peaks.

In an embodiment, removing material comprises controlling one or more of an angle, a taper, or a shadowing of one or more of the peaks. In an embodiment, one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

In an embodiment, the support peaks are formed to have peak heights within a given dimensional range. In an embodiment, the given dimensional range describes a flatness and/or coplanarity of the peaks.

In an embodiment, the one or more masks comprise one or more ion beam figuring masks. In an embodiment, the etcher comprises an ion beam.

In an embodiment, the surface is substantially planar and flat before material is removed from the surface. In an embodiment, the surface comprises a top surface of a burl. In an embodiment, the surface forms at least a portion of a wafer table, a wafer clamp gripping surface, a reticle clamp, or reticle handler, in a semiconductor manufacturing apparatus.

In an embodiment, removing material comprises a dry etching process.

In an embodiment, the target characteristic is roughness. In an embodiment, the roughness is about 100 nm or more by RMS, while the support peaks are formed to have peak heights within about 100 nm or less of each other.

In an embodiment, the surface comprises a top surface of a burl, and wherein a width of a given dimensional range of peak heights depends on a dimension of the top surface of the burl. In an embodiment, a width of the given dimensional range comprises about 1 um to about 500 um.

According to another embodiment, there is provided a non-transitory computer readable medium having instructions thereon, the instructions when executed by a computer causing the computer to: (1) facilitate masking of one or more portions of a surface; (2) cause an etcher to remove material from one or more unmasked portions of the surface; and (3) iteratively repeat (1) and (2) to reshape unmasked portions of the surface until one or more structures such as support peaks are formed such that regions of the surface between individual peaks have a target characteristic.

In an embodiment, the target characteristic is indicative of a desired topography of the surface. In an embodiment, the desired topography comprises one or more of a desired skewness, kurtosis, or p-value of a dimension associated with the plurality of support peaks. In an embodiment, the target characteristic is associated with a quantity and/or dimensional separation of the individual peaks.

In an embodiment, removing material comprises controlling one or more of an angle, a taper, or a shadowing of one or more of the peaks. In an embodiment, one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

In an embodiment, the support peaks are formed to have peak heights within a given dimensional range. In an embodiment, the given dimensional range describes a flatness and/or coplanarity of the peaks.

In an embodiment, the masking is performed by one or more ion beam figuring masks. In an embodiment, removing material is performed by an ion beam.

In an embodiment, the surface is substantially planar and flat before material is removed from the surface. In an embodiment, the surface comprises a top surface of a burl. In an embodiment, the surface forms at least a portion of a wafer table, a wafer clamp gripping surface, a reticle clamp, or reticle handler, in a semiconductor manufacturing apparatus.

In an embodiment, removing material comprises a dry etching process.

In an embodiment, the target characteristic is roughness. In an embodiment, the roughness is about 100 nm or more by RMS, while the support peaks are formed to have peak heights within about 100 nm or less of each other.

In an embodiment, the surface comprises a top surface of a burl, and wherein a width of a given dimensional range of peak heights depends on a dimension of the top surface of the burl. In an embodiment, a width of the given dimensional range comprises about 1 um to about 500 um.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 schematically depicts a lithography apparatus, according to an embodiment.

FIG. 2 schematically depicts an embodiment of a lithographic cell or cluster, according to an embodiment.

FIG. 3 illustrates contrasting examples of surfaces, according to an embodiment.

FIG. 4 illustrates a method for forming structures on a surface, according to an embodiment.

FIG. 5 illustrates iteratively using a series of masks and removing material from a surface to reshape the unmasked portions of the surface, according to an embodiment.

FIG. 6 illustrates how removing material comprises controlling an angle, a taper, a shadowing, and/or other characteristics of one or more of structures, such as the support peaks described herein, formed on a surface.

FIG. 7A illustrates an example of a support peak structure formed on a surface, according to an embodiment.

FIG. 7B illustrates an example of a plurality of support peak structures formed on a surface, according to an embodiment.

FIG. 8 is a block diagram of an example computer system, according to an embodiment.

FIG. 9 is a schematic diagram of a lithographic projection apparatus similar to FIG. 1, according to an embodiment.

### DETAILED DESCRIPTION

Gripping, clamping, and/or otherwise supporting a part in a precise orientation is challenging. In semiconductor manufacturing, for example, wafers are often gripped, clamped, and/or otherwise supported by surfaces that include burls (e.g., small protrusions from the surface). The burls are designed to have a specific flatness, friction with a wafer, and/or other properties. Wafer load grid (WLG) is an issue related to burl surface properties (e.g., friction). Methods have been developed to enhance WLG (e.g., stone roughening) but these methods do not always work as intended (e.g., in particular for clamps). These methods generally include forming a rougher finish on a given burl to add more texture. However, semiconductor and/or other similar grips, clamps, and/or support surfaces have a tight flatness requirement. As a desired roughness is increased (e.g., to enhance WLG), the tight flatness requirement if often not be able to be maintained.

Surfaces with a tightly controlled flatness and roughness (and/or other target surface topology) have been difficult to produce. Typically, attempts at such control involve polishing a surface flat, then adding roughness and/or other surface topology by removing material. However, these surfaces, which often comprise uncontrolled voids in a flat top surface of a burl, for example, are not desirable. Asperities are poorly controlled, and the voids often cause damage to the gripped, clamped, and/or otherwise supported part. For example, a part may catch the edges of burls on the surface, or a surface may carry particles that are transferred to the part, etc.

Advantageously, the present systems and methods utilize a series of masks to shape custom structures in a flat surface. For example, with the present systems and methods, one or more portions of a surface are masked; material is removed from one or more unmasked portions of the surface; and the masking and material removal are iteratively repeated to reshape the unmasked portions of the surface. The reshaping continues until a plurality of surface structures (e.g., support peaks and/or other structures) are formed, and regions of the surface between individual structures have a target characteristic, which is indicative of a desired topography of the surface. This facilitates precise control of individual structure shapes, distribution of the structures on the surface, sizes of the structures, structure density, tapers, edge shapes, surface depth, shadowing, etc.

By way of a brief introduction, in the present document, forming structures on a surface is described in the context of integrated circuit and/or semiconductor manufacturing. This is not intended to be limiting. One of ordinary skill in the art may apply principles of surface structure formation in other operations where precise structure formation is desired.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively. In addition, any use of the terms “reticle” or “mask” herein may be considered synonymous with the more general term “patterning device.”

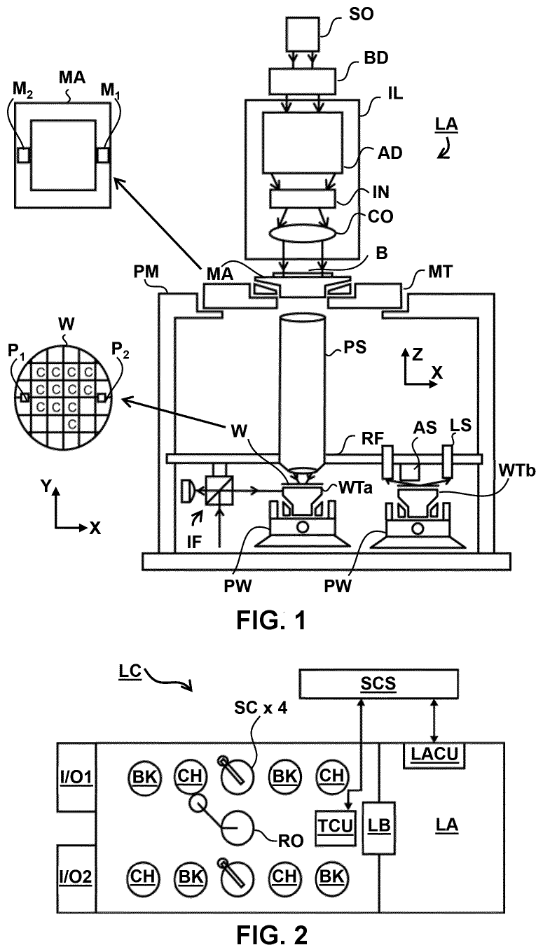

As an introduction, FIG. 1 schematically depicts an embodiment of a lithographic apparatus LA that may be included in and/or associated with the present systems and/or methods. The apparatus comprises: an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame (RF).

As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as G-outer and G-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e. the plane of the patterning device MA), through the projection system PS and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two dimensional grid, in an image plane of the projection system (i.e. the substrate table WTa or WTb) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e. the plane of the patterning device MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. 3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

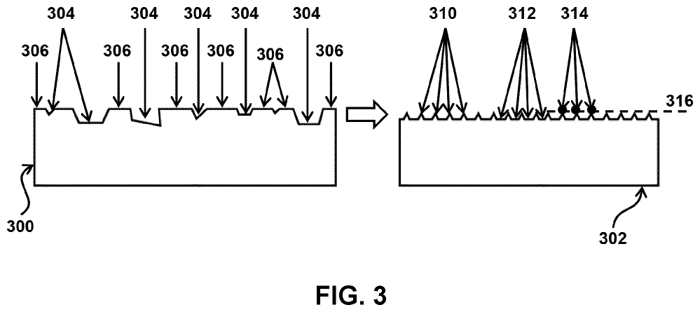

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. For example, contamination on reticle clamps (e.g., as described herein) may adversely affect overlay because clamping a reticle over such contamination will distort the reticle. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). This can be done as described above and as described, for example, in U.S. patent application publication US 2006-066855, which is incorporated herein in its entirety by reference. Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

Within a metrology system MET, a metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques. For example, a source mask optimization process is described in U.S. Pat. No. 9,588,438 titled “Optimization Flows of Source, Mask and Projection Optics”, which is incorporated in its entirety by reference.

As mentioned above related to FIGS. 1 and 2, a lithographic apparatus, a metrology tool, and/or a lithocell typically include a plurality of stage systems, supports, grippers, clamps, and/or other handling equipment, used to position a specimen, substrate, mask, or sensor arrangement relative to a reference or another component. Examples include the mask support MT and first positioner PM, the substrate support WT and the second positioner PW, a measurement stage arranged to hold a sensor and/or a substrate, the stage used in the inspection tool MT where a substrate W is positioned relative to e.g. a scanning electron microscope or some kind of scatterometer, grippers, clamps, and/or support surfaces associated with these components, and/or other items. These apparatuses may include grips, clamps, and/or other surfaces that benefit from the surface structure forming systems and methods described herein. The present systems, and/or methods may be used as stand-alone tools and/or techniques, and/or or used in conjunction with other semiconductor manufacturing processes, to accurately position, hold, and/or otherwise support substrates such as wafers with custom designed structures on support surfaces, which enhances the accurate transfer of complex designs to the wafers. These examples are not intended to be limiting. Even though the present systems and methods are described in the context of semiconductor manufacturing, the principles described herein may be used in other applications.

As described above, gripping, clamping, and/or otherwise supporting a part in a precise orientation is challenging. Semiconductor and/or other similar grips, clamps, and/or support surfaces have tight flatness and surface topology requirements. Surfaces with a tightly controlled flatness and surface topology have been difficult to produce. Typically, attempts at such control involve polishing a surface flat, then adding roughness (by removing material). However, the roughness, for example, may not be adequately controlled, and/or other issues may occur. There is often poor control of asperities, and voids in a surface often cause damage to the gripped, clamped, and/or otherwise supported part (e.g., wafer).

Advantageously, the present systems and methods utilize a series of masks to shape custom structures on a flat surface. For example, with the present systems and methods, one or more portions of a surface are masked; material is removed from one or more unmasked portions of the surface; and the masking and material removal are iteratively repeated to reshape the unmasked portions of the surface. The reshaping continues until a plurality of surface structures (e.g., support peaks and/or other structures) are formed, and regions of the surface between individual structures have a target characteristic, which is indicative of a desired topography of the surface (e.g., more than just vertical etching). This facilitates precise control of individual structure shapes, distribution of the structures on the surface, sizes of the structures, structure density, tapers, edge shapes, surface depth, shadowing, etc.

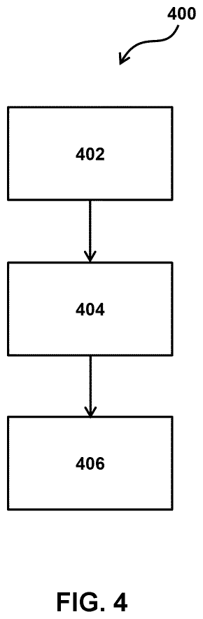

FIG. 3 illustrates contrasting examples of surfaces 300 and 302. Surfaces 300 and 302 may be top surfaces of a burl, for example, and/or other surfaces (however the example of a burl is not intended to be limiting). A burl is a bump and/or other protrusion from a larger surface. A series of burls may be used in a semiconductor stage system component, support, gripper, clamp, and/or other handling equipment components to contact and grip, clamp, and/or otherwise support a part such as a wafer. For example, a wafer may rest on a plurality of burls that protrude from a wafer table.

Surface 300 has been polished flat and then roughened (e.g., with stone roughening or another known process). Surface 300 includes a series of uncontrolled voids 304. Voids 304 have varying shapes, widths, depths, and/or other properties. Surface 300 also includes flat areas 306. Flat areas 306 are different sizes and shapes. This may produce areas of surface 300 that have different frictional forces when gripping, clamping, and/or otherwise supporting a part (e.g., a semiconductor wafer), and/or have other effects. The varying shapes, widths, depths, and/or other properties of voids 304 may cause a part to catch the edges of the burl and/or a void 304, surface 300 may carry particles in voids 304 that are transferred to the part, and/or other issues may occur.

In contrast, surface 302 includes a series of spikes 310, with controlled surface topography 312 between spikes 310. Spikes 310 and surface topography 312 are formed using the present systems and methods. For example, spikes 310 and surface topography are formed by (1) masking one or more portions of surface 302; (2) removing material from one or more unmasked portions (e.g., areas between spikes 310 that form surface topography 312) of surface 302; and (3) iteratively repeating (1) and (2) to reshape the unmasked portions of surface 302 until the plurality of spikes (e.g., support peaks) are formed such that regions of surface 302 between individual spikes 310 have surface topography 312 and/or other target characteristics. Spikes 310 are just one example of custom structures such as support peaks that may be formed in surface 302. In this example, the tips 314 of spikes 310 are coplanar so that they can support a part (e.g., a semiconductor wafer) in a substantially flat orientation. The dimensions and/or coplanarity of spikes 310 may be controlled to a nanometer level, for example, using the present systems and methods.

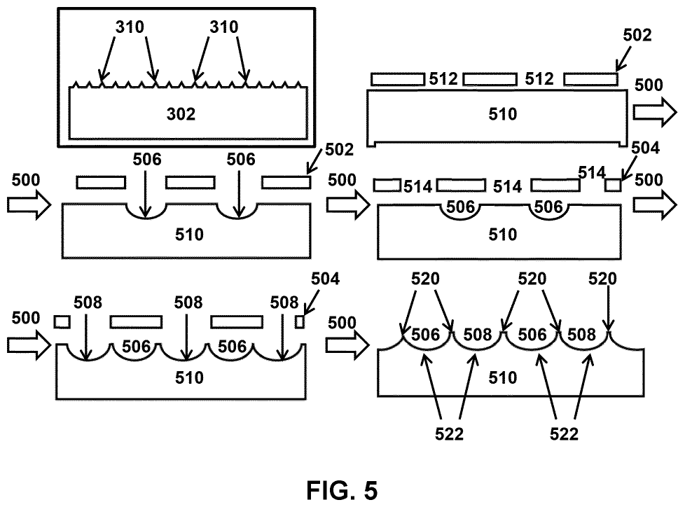

FIG. 4 illustrates a method 400 for forming structures on a surface (e.g., such as spikes 310 shown in FIG. 3). The structures may include support peaks and/or other structures, for example. The operations of method 400 presented below are intended to be illustrative. In some embodiments, method 400 may be accomplished with one or more additional operations not described, and/or without one or more of the operations discussed. For example, in some embodiments, method 400 need not include iteratively repeating the masking and material removal steps described below (e.g., only a single masking step and a single material removal step may be required). Additionally, the order in which the operations of method 400 are illustrated in FIG. 4 and described below is not intended to be limiting.

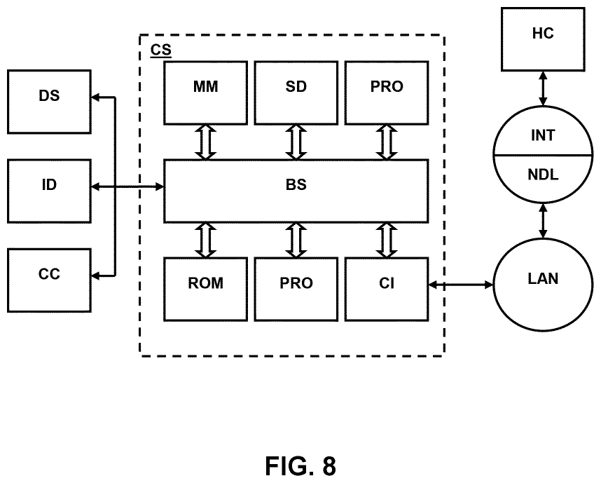

In some embodiments, one or more portions of method 400 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 400 in response to instructions stored electronically on an electronic storage medium. The one or more processing devices may include one or more devices configured through hardware, firmware, and/or software to be specifically designed for execution of one or more of the operations of method 400 (e.g., see discussion related to FIG. 8 below).

At an operation 402, one or more portions of a surface (e.g., surface 302 shown in FIG. 3) are masked. The surface is substantially planar and flat. The surface may be planar and flat after prior grinding, polishing, and/or other operations previously performed on the surface. In some embodiments, the surface comprises a top surface of a burl, for example, and/or other surfaces. In some embodiments, the surface forms at least a portion of a wafer table, a wafer clamp gripping surface, a reticle clamp, a reticle handler, and/or other components in a semiconductor manufacturing apparatus. The surface may be made from different materials. For example, the surface may be made from steel, silicon, diamond, Si—SiC, DLC, chromium nitride, Ti nitride, CrN, Cr, TiN, SiC, WC, fused silica/optical glasses, aluminum, and/or other materials.

Masking one or more portions of the surface for structure formation may share similarities with, but be different than, masking for photolithography as described above (though the base principles of masking—facilitating patterned material adjustment—remain the same). Masking for structure formation may include covering, blocking, protecting, and/or shielding specific areas of the surface. The covering or blocking may be performed by one or more masks and/or other devices. An individual mask may include a specific pattern or design with some areas configured to cover, block, protect, shield, etc., corresponding areas of the surface; and other areas not configured for such covering, blocking, protecting, shielding, etc. In some embodiments, a mask may be configured to be in physical contact with the surface. For example, the mask may rest against, be applied to, and/or otherwise coupled with a surface. In some embodiments a mask may be configured not to contact the surface. For example, a mask may be positioned proximate to, but not touching a surface. Whether a mask is configured to contact or not contact the surface, the mask is configured to be vacuum compatible, withstand a thermal load, and or have other properties that are compatible with the material removal operations described herein.

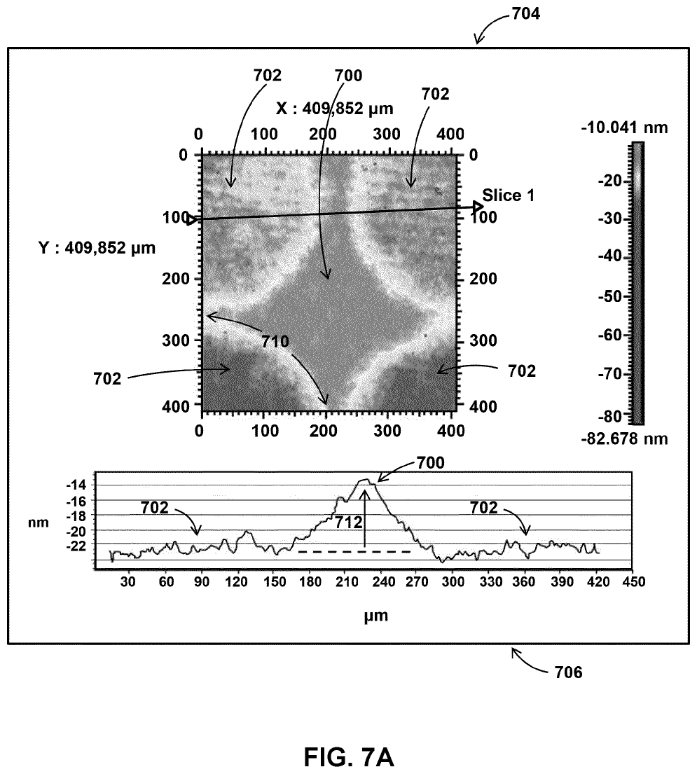

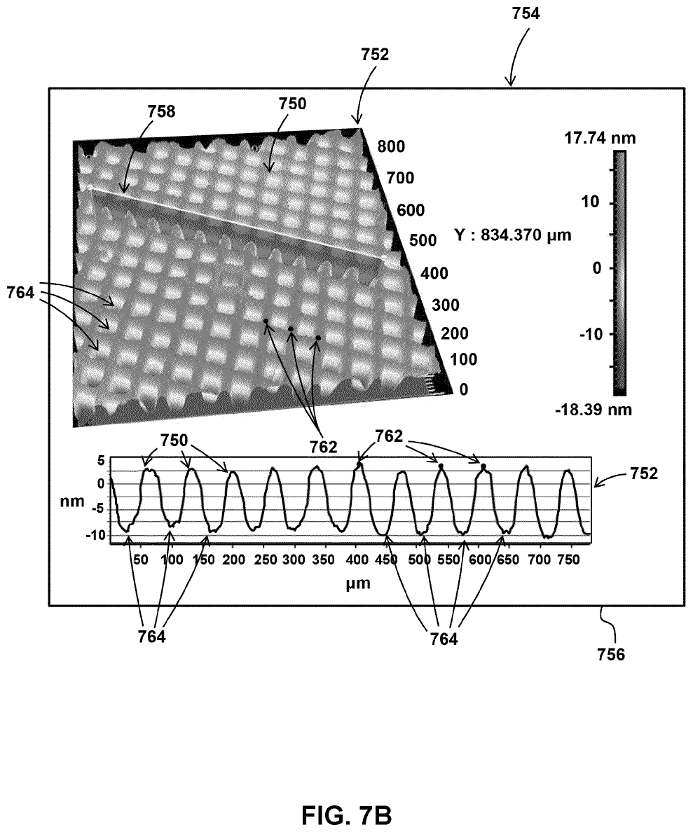

By way of a non-limiting example, the masking may be performed by one or more ion beam figuring masks and/or other masks. An ion beam figuring mask may be any mask configured to be used in an ion beam figuring chamber. Such masks may include a fused silica glass mask (see FIG. 6 as described below) made using selective laser etching, a tapered sapphire masked made using laser ablation, an off the shelf stainless steel mesh (see FIG. 7B as described below), and/or other masks. These examples are not intended to be limiting. The masking may be performed by any mask configured to function as described herein.

At an operation 404, material is removed from one or more unmasked portions of the surface. Removing material comprises physically eliminating material from the one or more unmasked portions of the surface. Removing material may include projecting and/or otherwise passing energy through the mask(s) and onto the unmasked portion of the surface. This may be performed in a vacuum environment so that the energy passed onto the unmasked portion of the surface is not interrupted by atmospheric particles, for example. Passing the energy through a mask may create a thermal load on the mask, and/or have other effects. The mask(s) and the vacuum environment, and/or other aspects of the present systems and methods, are configured to withstand this thermal load.

In some embodiments, removing material comprises a dry etching process. Dry etching may include etching without wet chemicals, for example. In some embodiments, removing material is performed by an ion beam (e.g., ion beam etching) and/or other components. An ion beam is a charged particle beam made up of ions. In some embodiments, the ion beam may be beam of positively charged argon atoms. Such an ion beam may have a specific, controllable, current density (e.g., intensity). The ion beam may be used to impinge on, and ablate, areas of the surface not covered by a portion of a mask. The ion beam removes material from the surface in the areas not covered by the mask in a controlled way. For example, an ion beam may be used to remove atoms from the surface, atom by atom, from unmasked areas of the surface.

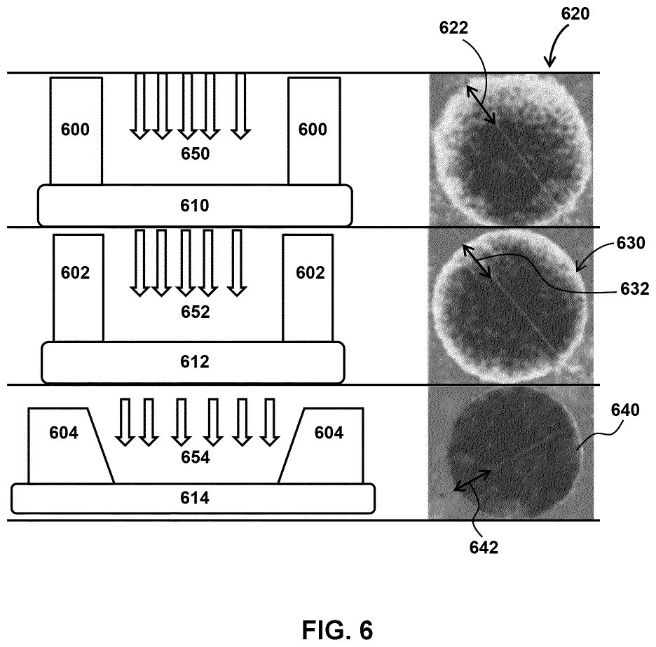

Removing material comprises controlling one or more of an angle, a taper, or a shadowing of one or more of the structures such as peaks. In some embodiments, one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), a cube corner, and/or other peaks. Examples of such features are further described below related to FIG. 5-7B.

Forming structures having these and other shapes and/or features may be accomplished by adjusting masks (e.g., mask size, shape, etc.), adjusting the energy used for material removal (e.g., ion source angle, aperture size, ion source (gas, energy, etc.) type, and/or other operations. For example, the dimensions and/or shapes of a mask can be used to control surface structure shapes. Making a mask thinner or thicker may change a structure edge sharpness (e.g., a thicker mask may soften an edge while a thinner mask may sharpen structure edges. Changing a mask sidewall angle (e.g., using or not using tapered mask sidewalls, changing a taper of the sidewalls, etc.) may further sharpen or soften such edges. In general, a mask can also be used to adjust structure shapes, structure distribution, density, size, and/or other characteristics of the structures formed on a surface.

As another example, changing an intensity, exposure time, and/or other properties of the energy used to ablate the unmasked areas of the surface can be used to adjust structure depths and/or other characteristics of the surface topology, facilitate use of the present systems and methods on a variety of surfaces made from a variety of materials, and/or have other uses. In some embodiments, increasing an energy intensity and/or exposure time may produce deeper structures in the surface. Conversely, decreasing an energy intensity and/or exposure time may produce shallower structures.

As a third example, the distance between the mask and the surface may be adjusted. This distance may be adjusted using an electronic positioning device (e.g., a device configured to move the mask and/or surface up or down in the “z” direction), shims, and/or other components. In some embodiments, the distance between the mask and the surface may be about 30, 40, 50, 60, 70, 80, 90, or 100 microns, a distance therebetween, and/or other distances. These example distances are not intended to be limiting. In some embodiments, the distance may correspond to an optical sweet spot where the present system and/or methods are enhanced compared to other distances. In some embodiments, this spot (e.g., distance) may change based on the size of the feature one wants to make.

At operation 406, the masking (operation 402) and material removal (operation 404) operations are iteratively repeated to reshape the unmasked portions of the surface. The unmasked portions of the surface are reshaped until the plurality of support peaks and/or other structures are formed such that regions of the surface between individual support peaks have a target characteristic. In some embodiments, the target characteristic is indicative of a desired topography of the surface. The topography may be the distribution of structures and/or features on the surface. For example, the target characteristic may indicate a desired distribution of support peaks, their shapes and sizes, and/or other information (e.g., a desired topography). In some embodiments, the desired topography comprises a desired skewness, kurtosis, p-value of a dimension associated with the plurality of support peaks, and/or other information indicative of a desired topography.

In some embodiments, the target characteristic is associated with a quantity and/or dimensional separation of the individual peaks. For example, the target characteristic be and/or indicate that a single structure such as an atomic force microscopy (AFM) tip, a Vicker's hardness tester tip, and/or other structures should be formed. As other examples, the target characteristic may be a density of peaks in a given area, a specification that there should be some given number of peaks, the peaks should be separated by a specific dimension in one or more directions, etc.

In some embodiments, the unmasked portions of the surface are formed such that peaks formed on the surface have peak heights within a given dimensional range. In some embodiments, the given dimensional range describes a flatness and/or coplanarity of the peaks. For example, in some embodiments, the structures such as support peaks are formed to have peak heights within about 500 nm or less of each other. In some embodiments, the structures such as support peaks are formed to have peak heights within about 100 nm or less of each other. In some embodiments, the structures such as support peaks are formed to have peak heights within about 50 nm or less of each other. In some embodiments, a given peak height (e.g., an amount a peak extends from its base) may be about 1 μm to about 1000 μm, for example. In some embodiments, a given peak height may be about 1 μm to about 500 μm, for example. In some embodiments, a given peak height may be about 1 μm to about 250 μm, for example.

In some embodiments, the surface comprises a top surface of a burl (e.g., as described herein) and/or other components, and a width of a given dimensional range of peak heights and/or a height of the peaks depends on a dimension of the top surface of the burl (or other component). For example, a larger burl may be require shorter peaks and/or a tighter peak height range to ensure a given part is held flat. This example is not intended to be limiting. Any combination of relatively tall or short peaks, with adequately tight peak height ranges may be used.

In some embodiments, the target characteristic is roughness. The roughness may be measured by a root mean square (RMS) of a surface's measured peaks and valleys, and or other measures of roughness. In some embodiments, the target characteristic may be a roughness of about 200 nm or more by RMS, for example. In some embodiments, the target characteristic may be a roughness of about 100 nm or more by RMS, for example. In some embodiments, the target characteristic may be a roughness of about 50 nm or more by RMS, for example.

FIG. 5 illustrates iteratively using 500 a series of masks 502, 504 and removing material 506, 508 from a surface 510 to reshape the unmasked portions 512, 514 of surface 510 (e.g., operations 402, 404, and 406 in FIG. 4). Unmasked portions 512, 514 of surface 510 are reshaped until a plurality of support peaks 520 (in this example) and/or other structures are formed such that regions 522 of surface 510 between individual support peaks 520 have a target surface topology and/or other characteristics. In this example, regions 522 have a scalloped or rounded profile between peaks 520. This process may be used to form the spikes 310 in surface 302 as shown in FIG. 3, for example.

In FIG. 5, a substantially flat surface 510 is masked with a first mask 502 (e.g., which may be an ion beam figuring mask and/or other masks as described herein). Material 506 is then removed from surface 510 in unmasked portions 512. Material removal may comprise etching (e.g., with an ion beam) and/or other material removal operations. Surface 510 may be masked again with a second mask 504, creating different unmasked portions 514, where material 508 is removed. As shown in FIG. 5, this reshapes the unmasked areas of surface 510. This process may be iteratively repeated as necessary until a plurality of support peaks 520 (in this example) and/or other structures are formed such that regions 522 of surface 510 between individual support peaks 520 have a target surface topology and/or other characteristics.

FIG. 6 illustrates how removing material (e.g., operation 404 in FIG. 4) comprises controlling an angle, a taper, a shadowing, and/or other characteristics of one or more of structures, such as the support peaks described herein, formed on a surface. As described above, in some embodiments, one or more individual peaks can comprise a spike, a block, a hemisphere, a bump, a fillet, a taper, a hole, a pyramid, a step, a nano hardness tester tip, a Vickers hardness tip, an atomic force microscopy (AFM tip), a cube corner, and/or other structures.

FIG. 6 illustrates how a mask 600, 602, 604 dimension and/or shape can be used to control surface 610, 612, 614 structure shapes (e.g. shadowing of round and/or cylindrical holes between peaks in this example). For example, in some embodiments, mask 600 may comprise a lmm thick fused silica mask used to form a round hole 620 in surface 610. This may result in a relatively large amount of shadowing 622 (as indicated by the gray scale color change). In some embodiments, mask 602 may comprise a 0.5 mm thick fused silica mask used to form a round hole 630 in surface 612. This may result in a medium (in this example) amount of shadowing 632 (as indicated by the gray scale color change). In some embodiments, mask 604 may comprise a 0.44 mm thick sapphire mask with a six degree taper used to form a round hole 640 in surface 614. This may result in a little to no shadowing 642 (as indicated by the lack of gray scale color change). Although not explicitly shown in FIG. 6, masks 600, 602, and 604 and/or similar masks may be used to control hole shape, distribution, size, density, taper, edge shape, and/or other topography characteristics.

FIG. 6 also illustrates radiation 650, 652, 654 (as one possible example of an etchant) impinging on unmasked areas of surfaces 610, 612, and 614. Radiation 650, 652, and/or 654 may comprise an ion beam and/or other radiation for example. The radiation may be used to control a depth of holes 620, 630, and/or 640, may allow processing of a variety of surface materials (e.g., silicon, diamond, etc.) and/or have other advantages. For example, an intensity and/or exposure time of the ion beam may be varied to create holes of varying depths in a surface. Purposely varying the radiation and/or other etchants, in combination with mask variation, facilitates precise control and/or adjustment of surface structure shape, distribution, size, density, tapers, edge shapes, depth, shadowing, angles, and/or other characteristics. These characteristics may be controlled and/or adjusted one at a time, in parallel, in series, and/or in other ways.

FIG. 7A illustrates an example of a support peak structure 700 formed on a surface 702. FIG. 7A illustrates a top view 704 and a profile view 706 of structure 700. FIG. 7A illustrates example dimensions in each view. The shape and dimensions of structure 700 are tightly controlled. The shape and dimensions are only examples, and are not intended to be limiting. Structure 700 was formed using the systems and methods described herein. As shown in view 704, structure 700 is generally diamond or pyramid shaped, but includes rounded surfaces 710 on the faces of the pyramid. As shown in view 706, structure 700 protrudes 712 from surface 702.

FIG. 7B illustrates an example of a plurality of support peak structures 750 formed on a surface 752. Structures 750 form a pattern of nano-divots, for example. FIG. 7B illustrates a perspective view 754 and a profile view 756 of structure 700. Profile view 756 is shown for slice 758 illustrated in view 754. FIG. 7A illustrates example dimensions in each view. The shapes and dimensions of structures 750 are tightly controlled. The shapes and dimensions are only examples, and are not intended to be limiting. Structures 750 were formed using the systems and methods described herein. As shown in view 754, structures 750 are generally waffle shaped, with rounded surfaces 760 at peaks 762 and valleys 764 of the waffle pattern. In this example, structures 750 were formed using an off the shelf stainless steel mesh shimmed at 50 microns (distance between the mask and surface). Using a mesh like this may be advantageous for components such as wafer tables and/or wafer clamps as the mesh may reduce an area for optical like contact while keeping the surface substantially flat to the nm level.

FIG. 8 is a block diagram of an example computer system CS, according to an embodiment. Computer system CS may assist in implementing the methods, flows, or the apparatus disclosed herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO, for example. Computer system CS includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS.

Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

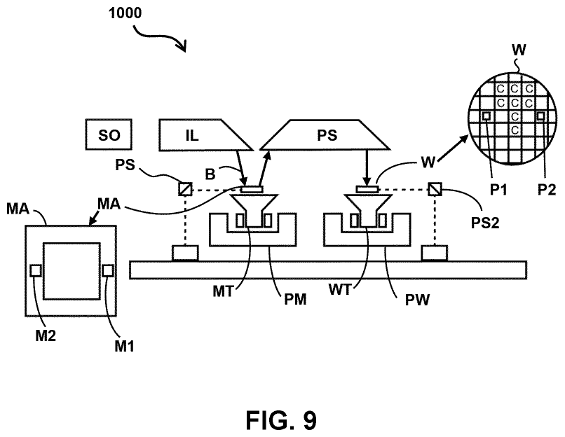

FIG. 9 schematically depicts an exemplary lithographic projection apparatus 1000 similar to and/or the same as the apparatus shown in FIG. 1 that can be used in conjunction with the techniques described herein. Apparatus 1000 may generally represent a DUV apparatus, for example, with a twin scan setup (this example is not intended to be limiting). The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means for setting the outer and/or inner radial extent (commonly referred to as σ-outer and σ-inner, respectively) of the intensity distribution in the beam. In addition, it will generally comprise various other components, such as an integrator and a condenser. In this way, the beam B impinging on the patterning device MA has a desired uniformity and intensity distribution in its cross-section.

It should be noted with regard to FIG. 9 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F2 lasing).

The beam subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means), the substrate table WT can be moved accurately, e.g. to position different target portions C in the path of the beam. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one operation (i.e., a single “flash”) onto a target portion C. The substrate table WT is then shifted in the x and/or y directions so that a different target portion C can be irradiated by the beam;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

The embodiments may further be described using the following clauses:

1. A method for forming a plurality of support peaks on a surface, comprising:
(1) masking one or more portions of the surface;
(2) removing material from one or more unmasked portions of the surface; and
(3) iteratively repeating (1) and (2) to reshape the unmasked portions of the surface until the plurality of support peaks are formed such that regions of the surface between individual support peaks have a target characteristic.

2. The method of clause 1, wherein the target characteristic is indicative of a desired topography of the surface.

3. The method of clause 2, wherein the desired topography comprises one or more of a desired skewness, kurtosis, or p-value of a dimension associated with the plurality of support peaks.

4. The method of any of clauses 1-3, wherein the target characteristic is associated with a quantity and/or dimensional separation of the individual peaks.

5. The method of any of clauses 1-4, wherein removing material comprises controlling one or more of an angle, a taper, or a shadowing of one or more of the peaks.

6. The method of any of clauses 1-5, wherein one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

7. The method of any of clauses 1-6, wherein the peaks are formed to have peak heights within a given dimensional range.

8. The method of clause 7, wherein the given dimensional range describes a flatness and/or coplanarity of the peaks.

9. The method of any of clauses 1-8, wherein the masking is performed by one or more ion beam figuring masks.

10. The method of any of clauses 1-9, wherein removing material is performed by an ion beam.

11. The method of any of clauses 1-10, wherein the surface is substantially planar and flat before material is removed from the surface.

12. The method of any of clauses 1-11, wherein the surface comprises a top surface of a burl.

13. The method of any of clauses 1-12, wherein the surface forms at least a portion of a wafer table, a wafer clamp gripping surface, a reticle clamp, or reticle handler, in a semiconductor manufacturing apparatus.

14. The method of any of clauses 1-13, wherein removing material comprises a dry etching process.

15. The method of any of clauses 1-14, wherein the target characteristic is roughness.

16. The method of clause 15, wherein the roughness is about 100 nm or more by RMS, while the support peaks are formed to have peak heights within about 100 nm or less of each other.

17. The method of any of clauses 1-16, wherein the surface comprises a top surface of a burl, and wherein a width of a given dimensional range of peak heights depends on a dimension of the top surface of the burl.

18. The method of clause 17, wherein a width of the given dimensional range comprises about 1 um to about 500 um.

19. A system for forming a plurality of support peaks on a surface, the system comprising:
(1) one or more masks configured for masking one or more portions of the surface; and
(2) an etcher configured for removing material from one or more unmasked portions of the surface;
wherein the one or more masks and the etcher are configured for iteratively repeating the masking and the material removal from the unmasked portions of the surface until the plurality of support peaks are formed such that regions of the surface between individual support peaks have a target characteristic.

20. The system of clause 19, wherein the target characteristic is indicative of a desired topography of the surface.

21. The system of clause 20, wherein the desired topography comprises one or more of a desired skewness, kurtosis, or p-value of a dimension associated with the plurality of support peaks.

22. The system of any of clauses 19-21, wherein the target characteristic is associated with a quantity and/or dimensional separation of the individual peaks.

23. The system of any of clauses 19-22, wherein removing material comprises controlling one or more of an angle, a taper, or a shadowing of one or more of the peaks.

24. The system of any of clauses 19-23, wherein one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

25. The system of any of clauses 19-24, wherein the peaks are formed to have peak heights within a given dimensional range.

26. The system of clause 25, wherein the given dimensional range describes a flatness and/or coplanarity of the peaks.

27. The system of any of clauses 19-26, wherein the one or more masks comprise one or more ion beam figuring masks.

28. The system of any of clauses 19-27, wherein the etcher comprises an ion beam.

29. The system of any of clauses 19-28, wherein the surface is substantially planar and flat before material is removed from the surface.

30. The system of any of clauses 19-29, wherein the surface comprises a top surface of a burl.

31. The system of any of clauses 19-30, wherein the surface forms at least a portion of a wafer table, a wafer clamp gripping surface, a reticle clamp, or reticle handler, in a semiconductor manufacturing apparatus.

32. The system of any of clauses 19-31, wherein removing material comprises a dry etching process.

33. The system of any of clauses 19-32, wherein the target characteristic is roughness.

34. The system of clause 33, wherein the roughness is about 100 nm or more by RMS, while the support peaks are formed to have peak heights within about 100 nm or less of each other.

35. The system of any of clauses 19-34, wherein the surface comprises a top surface of a burl, and

wherein a width of a given dimensional range of peak heights depends on a dimension of the top surface of the burl.

36. The system of clause 35, wherein a width of the given dimensional range comprises about 1 um to about 500 um.

37. A non-transitory computer readable medium having instructions thereon, the instructions when executed by a computer causing the computer to:
(1) facilitate masking of one or more portions of a surface;
(2) cause an etcher to remove material from one or more unmasked portions of the surface; and
(3) iteratively repeat (1) and (2) to reshape unmasked portions of the surface until one or more support peaks are formed such that regions of the surface between individual peaks have a target characteristic.

38. The medium of clause 37, wherein the target characteristic is indicative of a desired topography of the surface.

39. The medium of clause 38, wherein the desired topography comprises one or more of a desired skewness, kurtosis, or p-value of a dimension associated with a plurality of support peaks.

40. The medium of any of clauses 37-39, wherein the target characteristic is associated with a quantity and/or dimensional separation of the individual peaks.

41. The medium of any of clauses 37-40, wherein removing material comprises controlling one or more of an angle, a taper, or a shadowing of one or more of the peaks.

42. The medium of any of clauses 37-41, wherein one or more individual peaks comprise one or more of a spike, a block, a hemisphere, a bump, a fillet, a taper, a hole, a pyramid, a step, a nano hardness tester tip, a Vickers hardness tip, an atomic force microscopy (AFM tip), or a cube corner.

43. The medium of any of clauses 37-42, wherein the peaks are formed to have peak heights within a given dimensional range.

44. The medium of clause 43, wherein the given dimensional range describes a flatness and/or coplanarity of the peaks.

45. The medium of any of clauses 37-44, wherein the masking is performed by one or more ion beam figuring masks.

46. The medium of any of clauses 37-45, wherein removing material is performed by an ion beam.

47. The medium of any of clauses 37-46, wherein the surface is substantially planar and flat before material is removed from the surface.

48. The medium of any of clauses 37-47, wherein the surface comprises a top surface of a burl.

49. The medium of any of clauses 37-48, wherein the surface forms at least a portion of a wafer table, a wafer clamp gripping surface, a reticle clamp, or reticle handler, in a semiconductor manufacturing apparatus.

50. The medium of any of clauses 37-49, wherein removing material comprises a dry etching process.

51. The medium of any of clauses 37-50, wherein the target characteristic is roughness.

52. The medium of clause 51, wherein the roughness is about 100 nm or more by RMS, while the support peaks are formed to have peak heights within about 100 nm or less of each other.

53. The medium of any of clauses 37-52, wherein the surface comprises a top surface of a burl, and wherein a width of a given dimensional range of peak heights depends on a dimension of the top surface of the burl.

54. The medium of clause 53, wherein a width of the given dimensional range comprises about 1 um to about 500 um.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A method surface, comprising:
masking one or more portions of a surface;
removing material from one or more unmasked portions of the surface; and
iteratively repeating the masking and removing to reshape the unmasked portions of the surface until a plurality of support peaks are formed such that regions of the surface between individual support peaks have a target characteristic.

2. The method of claim 1, wherein the target characteristic is indicative of a desired topography of the surface.

3. The method of claim 2, wherein the desired topography comprises one or more selected from: a desired skewness, kurtosis, or p-value of a dimension associated with the plurality of support peaks.

4. The method of claim 1, wherein the target characteristic is associated with a quantity and/or dimensional separation of the individual support peaks.

5. The method of claim 1, wherein the removing material comprises controlling one or more selected from: an angle, a taper, or a shadowing of one or more of the individual support peaks.

6. The method of claim 1, wherein one or more of the individual support peaks comprise one or more selected from: a spike, a block, a hemisphere, a bump, a fillet, a taper, a hole, a pyramid, a step, a nano hardness rester tip, a Vickers hardness tip, an atomic force microscopy (AFM tip), or a cube corner.

7. The method of claim 1, wherein the support peaks are formed to have peak heights within a given dimensional range.

8. The method of claim 7, wherein the given dimensional range describes a flatness and/or coplanarity of the support peaks.

9. The method of claim 1, wherein the masking is performed by one or more ion beam figuring masks.

10. The method of claim 1, wherein the removing material is performed by an ion beam.

11. The method of claim 1, wherein the surface is substantially planar and flat before material is removed from the surface.

12. The method of claim 1, wherein the surface comprises a top surface of a burl.

13. The method of claim 1, wherein the surface forms at least a portion of a wafer table, a wafer clamp gripping surface, a reticle clamp, or reticle handler, in a semiconductor manufacturing apparatus.

14. The method of claim 1, wherein the removing material comprises a dry etching process.

15. The method of claim 1, wherein the target characteristic is roughness.

16. The method of claim 15, wherein the roughness is about 100 nm or more by RMS, while the support peaks are formed to have peak heights within about 100 nm or less of each other.

17. The method of claim 1, wherein the surface comprises a top surface of a burl, and wherein a width of a given dimensional range of peak heights depends on a dimension of the top surface of the burl.

18. The method of claim 17, wherein a width of the given dimensional range comprises about 1 um to about 500 μm.

19. A system for forming a plurality of support peaks on a surface, the system comprising:
(1) one or more masks configured to mask one or more portions of the surface; and
(2) an etcher configured to remove material from one or more unmasked portions of the surface,
wherein the one or more masks and the etcher are configured to iteratively repeat masking one or more portions of the surface using the one or more masks and the material removal from the unmasked portions of the surface using the etcher, until the plurality of support peaks are formed such that regions of the surface between individual support peaks have a target characteristic.

20. A non-transitory computer readable medium having instructions therein, the instructions, when executed by a computer system, configured to cause the computer system to at least:
facilitate masking of one or more portions of a surface;
cause an etcher to remove material from one or more unmasked portions of the surface; and
iteratively repeat the facilitation of the masking and the causing of the etcher to remove material, to reshape unmasked portions of the surface until one or more support peaks are formed such that regions of the surface between individual peaks have a target characteristic.
